(19) United States
(12) Patent Application Publication
(10) Pub. No.: US 2004/0256353 A1
(43) Pub. Date: Dec. 23, 2004

(54) Method and system for deep trench silicon etch

(75) Inventors: Siddhartha Panda, Beacon, NY (US); Aelan Mosden, Poughkeepsie, NY (US); Richard Wise, New Windsor, NY (US); Kenro Sugiyama, Cambridge, MA (US); Joseph Gregory Camilleri, Wappingers Falls, NY (US)

Correspondence Address: PILLSBURY WINTHROP, LLP, P.O. BOX 10500, MCLEAN, VA, 22102, US

(73) Assignees: Tokyo Electron Limited, Tokyo (JP); International Business Machines Corporation, Armonk, NY

(21) Appl. No.: 10/821,201

(22) Filed: Apr. 9, 2004

Related U.S. Application Data
(60) Provisional application No. 60/464,959, filed on Apr. 24, 2003.

(51) Int. Cl. H01B 13/00; C23C 14/00; C23C 14/32

(52) U.S. Cl. 216/18

(57) ABSTRACT

A method and system for deep trench silicon etch is presented. The method comprises introducing a reactive process gas and a Noble gas to a plasma processing system, wherein the reactive process gas comprises two or more of HBr, a fluorine-containing gas, and O₂, and the Noble gas comprises at least one of He, Ne, Ar, Xe, Kr, and Rn. Additionally, radio frequency (RF) power is applied to the substrate holder, upon which the substrate rests, at two different frequencies. The first RF frequency is greater than 10 MHz, and the second frequency is less than 10 MHz.

This non-provisional application claims the benefit of U.S. Provisional Application No. 60/464,959, filed Apr. 24, 2003, the contents of which are incorporated in their entirety herein by reference

### FIELD OF THE INVENTION

The present invention relates to a method and system for deep trench silicon etching, and, more particularly, a method and system for deep trench silicon etching with the addition of a rare gas.

### BACKGROUND OF THE INVENTION

The fabrication of integrated circuits (IC) in the semiconductor industry typically employs plasma to create and assist surface chemistry within a plasma reactor necessary to remove material from and deposit material to a substrate. For example, dry plasma etching of silicon is utilized in forming deep trenches that are used as storage capacitors in many types of memory applications. Common gas chemistries used for these types of applications include NF₃ (and other fluorine sources), O₂, and HBr. The etched silicon reacts with the gases to form a passivation chemistry, which deposits on the trench bottom, sidewalls, and mask surface; see FIG. 1 wherein a silicon layer 1 having an overlying nitride layer 2 and borosilicate glass (BSG) layer 4 comprises a feature 6 with passivation chemistry 8. This continually deposited passivation film protects the sidewalls from lateral attack and thus preserves the trench as the etch proceeds. The film on the trench bottom, subjected to energetic ion flux is removed thereby exposing silicon for further etch. Hence, formation of these trenches involves an interplay between processes of film deposition, film sputter and silicon etch.

Linked to this interplay is the balance of chemical and physical (or sputter) components of the process. In general, it is suspected that highly reactive fluorine radicals dominate the chemical process while the heavier bromine ions govern the physical process.

As feature sizes fall below 0.15 micron, deep trench aspect ratios begin to exceed a value of 40, and, consequently, the silicon etch of such features becomes progressively more difficult. Therefore, new processes are required, that follow the aforementioned interplay of physical and chemical processes, in order to produce optimal etch characteristics such as etch rate, etch selectivity (silicon-to-mask), mask erosion, and passivation film thickness for deep trench etch.

### SUMMARY OF THE INVENTION

The present invention presents a method and system for deep trench silicon etching.

A method of etching a silicon-comprising substrate supported by a substrate holder in a plasma processing system includes: placing the silicon-comprising substrate on the substrate holder; introducing a reactive process gas to a process space in the plasma processing system, the reactive process gas comprising two or more of O₂, a fluorine-containing gas, and HBr; introducing a Noble gas to the process space in the plasma processing system, the Noble gas comprising at least one of Ar, Kr, He, Ne, Xe, and Rn; applying a first radio frequency (RF) power to the substrate holder, wherein the first RF power comprises a frequency greater than 10 MHz; applying a second RF power to the substrate holder, wherein the second RF power comprises a frequency less than 10 MHz; and etching the silicon film. The method can further comprise applying a magnetic field to the process space, wherein the magnetic field strength ranges from 5 to 500 Gauss.

Additionally, a plasma processing system for etching a silicon-comprising substrate includes: a processing chamber comprising a process space adjacent the substrate; a substrate holder coupled to the processing chamber and configured to support the substrate; means for introducing a reactive process gas to the process space in the processing chamber, the reactive process gas comprising two or more of O₂, a fluorine-containing gas, and HBr; means for introducing a Noble gas to the process space in the processing chamber, the Noble gas comprising at least one of Ar, Kr, He, Ne, Xe, and Rn; means for applying a first radio frequency (RF) power to the substrate holder, wherein the first RF power comprises a frequency greater than 10 MHz; and means for applying a second RF power to the substrate holder, wherein the second RF power comprises a frequency less than 10 MHz. The plasma processing system can further comprise means for applying a magnetic field to the process space, wherein the magnetic field strength ranges from 5 to 500 Gauss.

### BRIEF DESCRIPTION OF THE DRAWINGS

In the accompanying drawings:

FIG. 1 shows a simplified schematic diagram of the formation of a passivation film in a trench;

FIG. 2 presents a schematic diagram of a plasma processing system according to an embodiment of the present invention;

FIG. 3A presents a first result of a first set of data for an embodiment of the present invention;

FIG. 3B presents a second result of the first set of data for an embodiment of the present invention;

FIG. 3C presents a third result of the first set of data for an embodiment of the present invention;

FIG. 4A presents a first result of a second set of data for another embodiment of the present invention;

FIG. 4B presents a second result of the second set of data for another embodiment of the present invention;

FIG. 4C presents a third result of the second set of data for another embodiment of the present invention;

FIG. 5A presents a first result of a third set of data for another embodiment of the present invention;

FIG. 5B presents a second result of the third set of data for another embodiment of the present invention;

FIG. 5C presents a third result of the third set of data for another embodiment of the present invention; and

FIG. 6 presents a method of etching a feature in a silicon layer according to an embodiment of the present invention.

### DETAILED DESCRIPTION OF AN EMBODIMENT

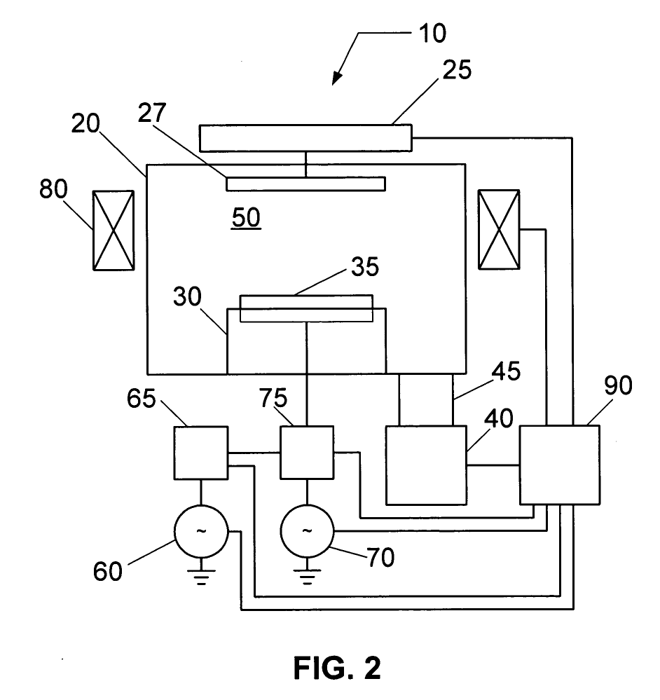

According to the embodiment depicted in FIG. 2, plasma processing system 10 comprises plasma processing chamber 20, gas distribution system 25 coupled to the plasma processing chamber 20, substrate holder 30 coupled to the plasma processing chamber 20, upon which a substrate 35 to be processed is affixed, and vacuum pumping system 40 coupled to the plasma processing chamber 20 via pumping duct 45. Substrate 35 can be, for example, a semiconductor substrate, a wafer or a liquid crystal display. Plasma processing chamber 20 can be, for example, configured to facilitate the generation of plasma in processing region 50 adjacent a surface of substrate 35. An ionizable gas or mixture of gases is introduced via a gas injection system (not shown) and the process pressure is adjusted. For example, a control mechanism (not shown) can be used to throttle the vacuum pumping system 40. Plasma can be utilized to create materials specific to a pre-determined material process, and/or to aid the removal of material from the exposed surfaces of substrate 35. The plasma processing system 10 can be configured to process 200 mm substrates, 300 mm substrates, or larger.

Substrate 35 can be, for example, affixed to the substrate holder 30 via an electrostatic clamping system. Furthermore, substrate holder 30 can, for example, further include a cooling system including a re-circulating coolant flow that receives heat from substrate holder 30 and transfers heat to a heat exchanger system (not shown), or when heating, transfers heat from the heat exchanger system. Moreover, gas can, for example, be delivered to the back-side of substrate 35 via a backside gas system to improve the gas-gap thermal conductance between substrate 35 and substrate holder 30. Such a system can be utilized when temperature control of the substrate is required at elevated or reduced temperatures. For example, the backside gas system can comprise a two-zone or three-zone gas distribution system, wherein the helium gas gap pressure can be independently varied between the center and the edge of substrate 35. In other embodiments, heating/cooling elements, such as resistive heating elements, or thermoelectric heaters/coolers can be included in the substrate holder 30, as well as the chamber wall of the plasma processing chamber 20 and any other component within the plasma processing system 10.

In the embodiment shown in FIG. 2, substrate holder 30 can comprise an electrode through which RF power is coupled to the processing plasma in process space 50. For example, substrate holder 30 is electrically biased via the transmission of RF power at a first RF frequency from a first RF generator 60 through a first impedance match network 65 to substrate holder 30. The RF bias at the first frequency can serve to heat electrons to form and maintain plasma. In this configuration, the system can operate as a reactive ion etch (RIE) reactor, wherein the chamber and an upper gas injection electrode serve as ground surfaces. A typical frequency for the RF bias can range from 10 MHz to 100 MHz. RF systems for plasma processing are well known to those skilled in the art of RF system design.

Additionally, substrate holder 30 can be electrically biased via the transmission of RF power at a second RF frequency from a second RF generator 70 through a second impedance match network 75. The RF bias at the second frequency can serve to control ion energy at the surface of substrate 35. A typical frequency for the RF bias can range from 0.1 MHz to 10 MHz. RF systems for plasma processing are well known to those skilled in the art of RF system design.

As is known to those skilled in the art of match network design, impedance match networks 65 and 75 serve to improve the transfer of RF power to plasma in plasma processing chamber 20 by reducing the reflected power. Match network topologies (e.g. L-type, 7-type, T-type, etc.) and automatic control methods are well known to those skilled in the art of impedance match network design.

Additionally, plasma processing system 10 can further comprise either a stationary, or mechanically or electrically rotating magnet system 80, in order to potentially increase plasma density and/or improve plasma processing uniformity, in addition to those components described with reference to FIG. 2. The magnetic field strength can range from 5 to 500 Gauss, i.e. 170 Gauss. The design and implementation of a rotating magnetic field is well known to those skilled in the art of magnet systems.

As shown in FIG. 2, plasma processing system 10 comprises gas distribution system 25. In one embodiment, gas distribution system 25 comprises a showerhead gas injection system having a gas distribution electrode 27. The gas distribution electrode 27 can comprise a gas distribution assembly (not shown), and a gas distribution plate (not shown) coupled to the gas distribution assembly and configured to form a gas distribution plenum (not shown). Although not shown, gas distribution plenum can comprise one or more gas distribution baffle plates. The gas distribution plate further comprises one or more gas distribution orifices to distribute a process gas from the gas distribution plenum to the process space 50 within plasma processing chamber 20. Additionally, one or more gas supply lines (not shown) can be coupled to the gas distribution plenum through, for example, the gas distribution assembly in order to supply a process gas comprising one or more gases. The process gas can, for example, comprise a reactive gas including at least one of a fluorine-containing gas, such as NF₃, SiF₄, or SF₆, HBr, and O₂, and a Noble gas (i.e., at least one of He, Ne, Ar, Xe, Kr, and Rn, or any mixture thereof.

Vacuum pump system 40 can, for example, include a turbo-molecular vacuum pump (TMP) capable of a pumping speed up to 5000 liters per second (and greater) and a gate valve for throttling the chamber pressure. In conventional plasma processing devices utilized for dry plasma etch, a 1000 to 3000 liter per second TMP is generally employed. TMPs are useful for low pressure processing, typically less than 1000 mTorr. For high pressure processing (i.e., greater than 1000 mTorr), a mechanical booster pump and dry roughing pump can be used. Furthermore, a device for monitoring chamber pressure (not shown) can be coupled to the plasma processing chamber 10. The pressure measuring device can be, for example, a Type 628B Baratron absolute capacitance manometer commercially available from MKS Instruments, Inc. (Andover, Mass.).

Referring still to FIG. 2, a controller 90 can be coupled to processing system 10 to facilitate monitoring and control of the system components. Controller 90 comprises a microprocessor, memory, and a digital I/O port capable of generating control voltages sufficient to communicate and activate inputs to plasma processing system 10 as well as monitor outputs from plasma processing system 10. Moreover, controller 90 can be coupled to and can exchange information with first RF generator 60, first impedance match network 65, second RF generator 70, second impedance match network 75, magnet system 80, gas distribution system 25, vacuum pump system 40, and/or plasma processing chamber 20. In alternate embodiments, controller 90 can be coupled to and exchange information with a backside gas delivery system (not shown), a substrate/substrate holder temperature measurement system (not shown), and/or a electrostatic clamping system (not shown). For example, a program stored in the memory can be utilized to activate the inputs to the aforementioned components of plasma processing system 10 according to a process recipe in order to perform the method of etching a silicon layer. One example of controller 90 is a DELL PRECISION WORKSTATION 610™, available from Dell Corporation, Austin, Tex.

In one embodiment, a process gas comprising a fluorine-containing gas, O₂, HBr, and a Noble gas is utilized as a method of etching a feature in silicon. The fluorine-containing gas can comprise at least one of NF₃, SiF₄, or SF₆. The Noble gas comprises at least one of He, Ne, Ar, Xe, Kr, and Rn, or any mixture thereof. For example, the feature can comprise an opening having a sub-0.15 micron dimension, and the aspect ratio of the feature etched can exceed a value of 40.

In the following discussion, a method of etching a feature in silicon utilizing a plasma processing device is presented. For example, the plasma processing device comprises various elements, such as those described in FIG. 2.

In one embodiment, the method of etching a feature in silicon comprises a NF₃/SiF₄/O₂/HBr/Noble gas based chemistry. In an alternate embodiment, the method of etching a feature in silicon comprises a NF₃/O₂/HBr/Noble gas based chemistry. The Noble gas comprises at least one of He, Ne, Ar, Xe, Kr, and Rn. For example, a process parameter space can comprise a chamber pressure of 5 to 1000 mTorr, a first RF signal power i.e ranging from 300 to 2000 W, and a second RF signal power ranging from 300 to 2000 W. Also, the frequency for the first RF signal can range from 10 MHz to 100 MHz, e.g., 40 MHz. In addition, the frequency for the second RF signal can range from 0.1 MHz to 10 MHz, e.g., 3.2 MHz. Additionally, a rotating magnetic field can be applied to the process space, wherein the magnetic field strength ranges from 5 to 500 Gauss, e.g. 170 Gauss. Typically, the flow rate of HBr can be ten (10) times the flow rate of NF₃ and fifteen (15) times the flow rate of 2. For example, the flow rate of HBr can range from 25 to 1000 sccm (e.g. 300 sccm), the flow rate of NF₃ can range from 5 to 200 sccm (e.g. 35 sccm), the flow rate of 02 can range from 2 to 100 sccm (e.g. 20 sccm), and the flow rate of SiF₄ can range from 0 to 200 sccm (e.g. 20 sccm).

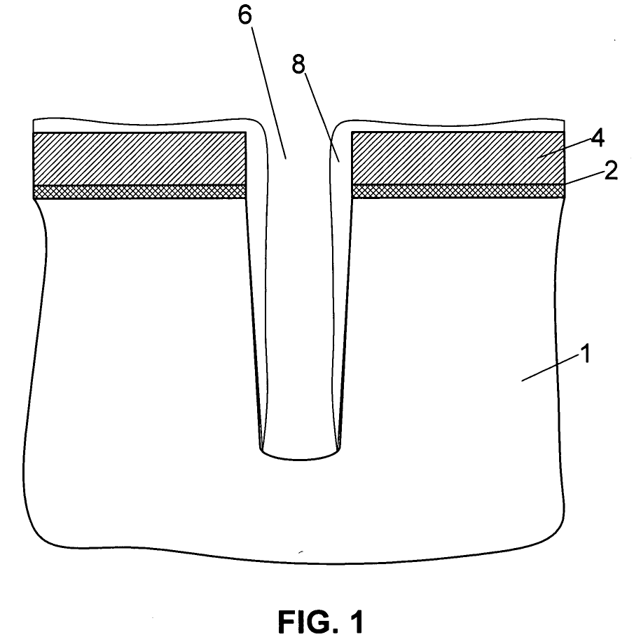

In a series of examples, experiments are described in which 200 mm diameter silicon substrates of <100> orientation with p-type dopant were used. The hardmask stack comprises deposited oxide and nitride films, which were patterned by KrF and ArF photoresist; see FIG. 1. Only the oxide layer (BSG) served as a mask for the silicon etch. The pattern factor (ratio of the unmasked silicon surface to the total surface based on design data) was approximately 18%. Furthermore, during these experiments, the substrate holder (i.e., element 30 in FIG. 2) was maintained at 90 degrees C.

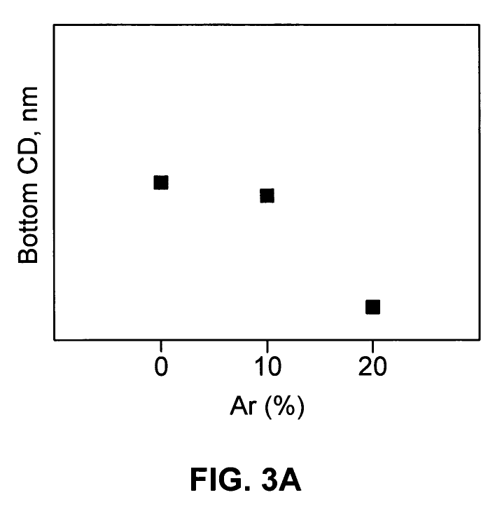

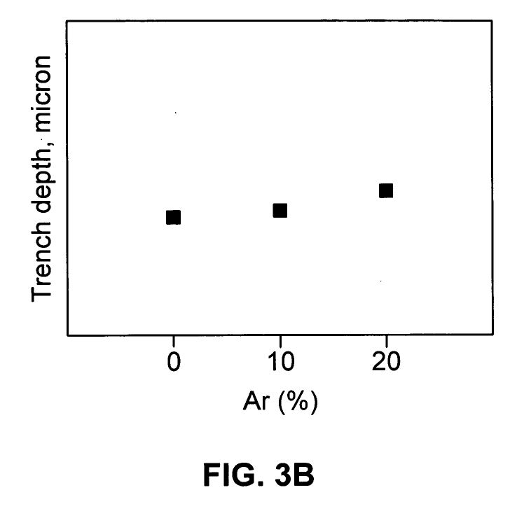

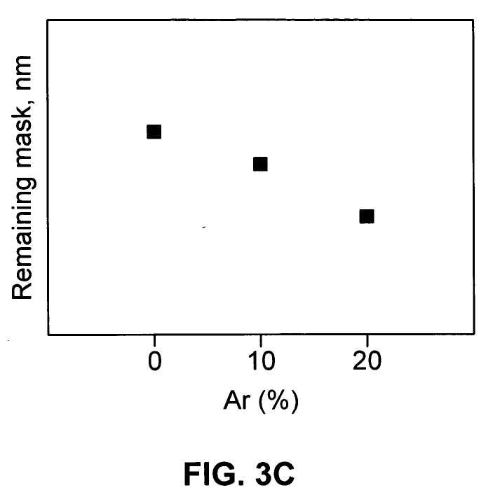

In a first example, the flow rates of NF₃ and 02 are maintained constant, and the flow rate of HBr is partially replaced with Ar. FIGS. 3A through 3C indicate that the partial replacement of the flow rate of HBr by Ar causes a reduction in bottom critical dimension (CD) (FIG. 3A), an increase in feature depth (FIG. 3B), an increase in passivation layer thickness, and an increase in mask erosion (FIG. 3C).

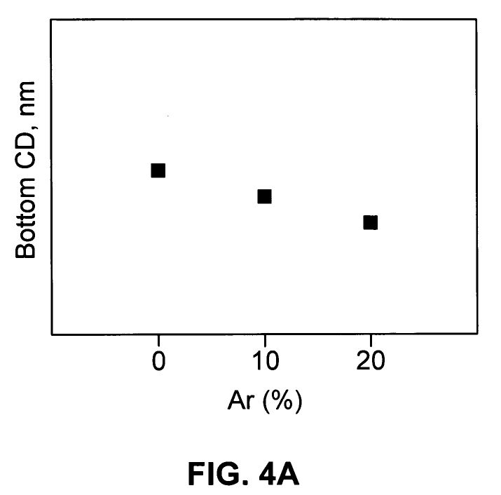

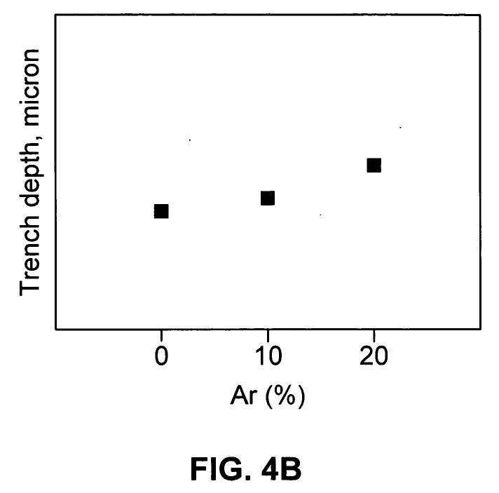

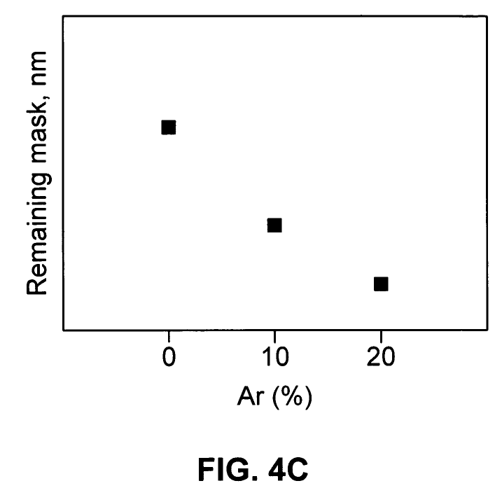

In a second example, the flow rate of NF₃ is held constant, and the flow rate of HBr is partially replaced with Ar; however, the flow rate of O₂ is reduced in order to maintain a substantially constant bottom CD. For example, the flow rate of O₂ was reduced by 2 sccm for the 20% dilution case, and 3 sccm for the 30% dilution case. As in the first example, the feature depth increased with Ar dilution, while mask erosion also increased; see FIGS. 4A through 4C.

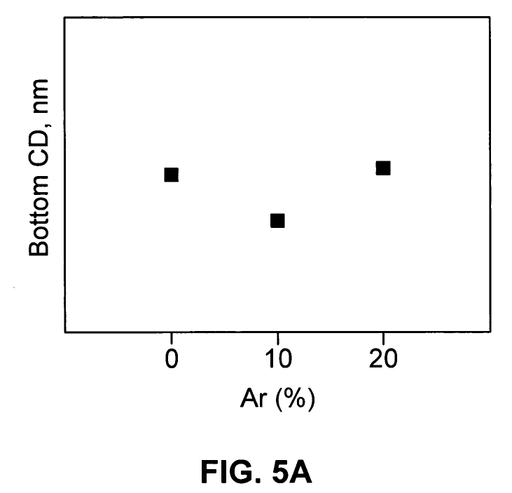

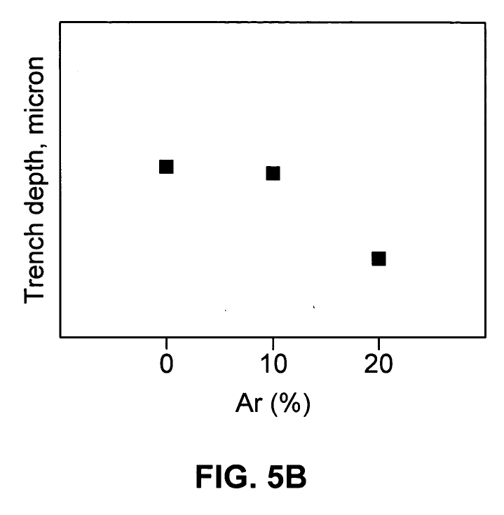

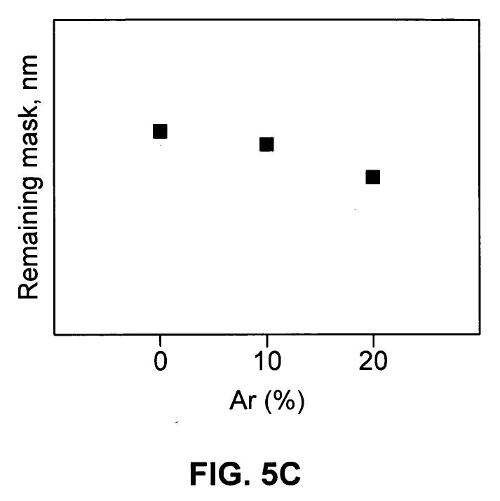

In a third example, the flow rates of NF₃, O₂, and HBr are all partially replaced by Ar. FIGS. 5A through 5C indicate that the bottom CD initially decreses and then increases above an Ar dilution of 10% (FIG. 5A), the feature depth increases with Ar dilution (FIG. 5B), and the mask erosion increases with Ar dilution (FIG. 5C).

In a fourth example (not shown), 20% of the flow rate of HBr is replaced with He. As with Ar dilution, He dilution leads to an increase in feature depth; however, at the expense of an increase in mask erosion.

In summary, for example, the addition of the Noble gas to the reactive process gas during deep trench silicon etch can facilitate greater throughput due to the greater etch rate.

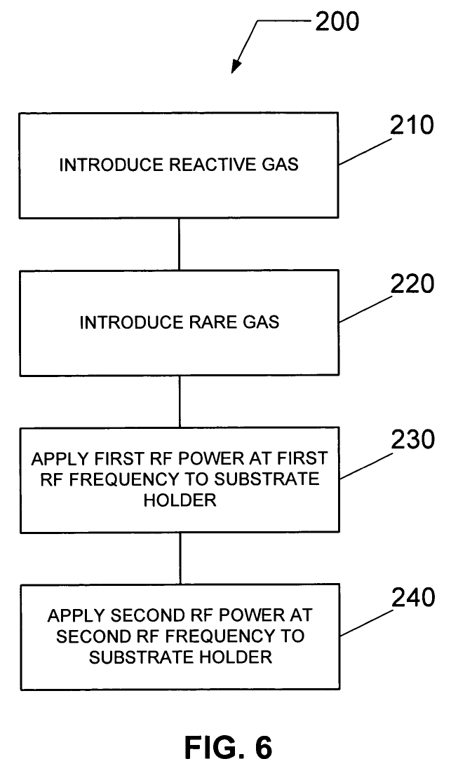

FIG. 6 presents a flow chart 200 describing a method of etching a feature in a silicon layer. The method begins in 210 with introducing a reactive process gas to a processing chamber, such as the one described in FIG. 2. The reactive gas comprises at least one of a fluorine-containing gas, O₂, and HBr. For example, the fluorine-containing gas can comprise NF₃ or SF₆. In 220, a Noble gas is introduced to the processing chamber. The Noble gas comprises at least one of He, Ne, Ar, Xe, Kr, and Rn.

In 230, a first RF signal at a first RF frequency and a first power is applied to the substrate holder upon which the substrate comprising the silicon layer rests. The first RF frequency can, for example, comprise a frequency ranging from 10 to 100 MHz; e.g. 40 MHz. In 240, a second RF signal at a second RF frequency and a second power is applied to the substrate holder upon which the substrate rests. The second RF frequency can, for example, comprise a frequency ranging from 0.1 to 10 MHz; e.g. 3.2 MHz. Alternately, a magnetic field can be applied to the process space overlying the substrate. The magnetic field can be stationary or rotating. For example, the strength of the magnetic field can range from 5 to 500 Gauss, e.g. 170 Gauss.

Although only certain exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

What is claimed is:

1. A method of etching a silicon-comprising substrate holder in a plasma processing system comprising:
placing said silicon-comprising substrate on said substrate holder;
introducing a reactive process gas to a process space in said plasma processing system, said reactive process gas comprising two or more of O₂, a fluorine-containing gas, and HBr;
introducing a Noble gas to said process space in said plasma processing system;
applying a first radio frequency (RF) signal to said substrate holder, wherein said first RF signal comprises a frequency greater than 10 MHz;
applying a second RF signal to said substrate holder, wherein said second RF signal comprises a frequency less than 10 MHz; and
etching said silicon film.

2. The method as recited in claim 1 further comprising:
applying a magnetic field to said process space, wherein said magnetic field comprises a magnetic field strength ranging from 5 to 500 Gauss.

3. The method as recited in claim 1, wherein said fluorine-containing gas comprises at least one of NF₃, SiF₄, and SF₆.

4. The method as recited in claim 1, wherein said first RF frequency is 40 MHz and said second RF frequency is 3.2 MHz.

5. The method as recited in claim 1, wherein said reactive process gas comprises HBr, O₂, and NF₃.

6. The method as recited in claim 5, wherein a flow rate of said HBr is about ten times greater than a flow rate of said NF₃, and said flow rate of said HBr is about fifteen times greater than a flow rate of said O₂.

7. The method as recited in claim 5, wherein a flow rate of said rare gas replaces said flow rate of said HBr by an amount up to and including 80%.

8. The method as recited in claim 5, wherein a flow rate of said rare gas replaces said flow rates of said HBr, said NF₃, and said O₂ by an amount up to and including 80%.

9. A plasma processing system for etching a silicon-comprising substrate comprising:
a processing chamber comprising a process space adjacent said substrate;
a substrate holder coupled to said processing chamber and configured to support said substrate;
means for introducing a reactive process gas to said process space in said processing chamber, said reactive process gas comprising two or more of O₂, a fluorine-containing gas, and HBr;
means for introducing a Noble gas to said process space in said processing chamber;
a first system which applies a first radio frequency (RF) signal to said substrate holder, wherein said first RF signal comprises a frequency greater than 10 MHz; and
a second system which applies a second RF signal to said substrate holder, wherein said second RF signal comprises a frequency less than 10 MHz.

10. The plasma processing system as recited in claim 9 further comprising means for applying a magnetic field to said process space, wherein said magnetic field comprises a magnetic field strength ranging from 5 to 500 Gauss.

11. The plasma processing system as recited in claim 9, wherein said fluorine-containing gas comprises at least one of NF₃, SiF₄, and SF₆.

12. The plasma processing system as recited in claim 9, wherein said first RF frequency is 40 MHz and said second RF frequency is 3.2 MHz.

13. The plasma processing system as recited in claim 1, wherein said reactive process gas comprises HBr, O₂, and NF₃.

14. The plasma processing system as recited in claim 13, wherein a flow rate of said HBr is about ten times greater than a flow rate of said NF₃, and said flow rate of said HBr is about fifteen times greater than a flow rate of said O₂.

15. The plasma processing system as recited in claim 13, wherein a flow rate of said rare gas replaces said flow rate of said HBr by an amount up to and including 80%.

16. The plasma processing system as recited in claim 13, wherein a flow rate of said rare gas replaces said flow rates of said HBr, said NF₃, and said O₂ by an amount up to and including 80%.
